(19) United States
(12) Patent Application Publication
(10) Pub. No.: US 2012/0233856 A1
(43) Pub. Date: Sep. 20, 2012

(54) APPARATUS FOR MANUFACTURING LIGHT EMITTING DEVICE PACKAGE AND METHOD OF MANUFACTURING LIGHT EMITTING DEVICE PACKAGE USING THE SAME

(76) Inventors: Kwan Young OH, Yongin (KR); Young Hee Song, Seongnam (KR); Sung Soo Park, Suwon (KR); Kyung Mi Moon, Suwon (KR)

(21) Appl. No.: 13/421,533

(22) Filed: Mar. 15, 2012

(30) Foreign Application Priority Data
Mar. 15, 2011 (KR) 10-2011-0022761

(51) Int. Cl. H05K 3/00; B23P 19/00

(52) U.S. Cl. 29/829; 29/739

(57) ABSTRACT

There is provided an apparatus and method for manufacturing a light emitting device package improved in terms of the reliability and process efficiency of a light emitting device. The apparatus includes a heating block including a recessed portion provided in an area in which a light emitting device package is disposed, and a protruding portion disposed within the recessed portion while corresponding to a recess formed in a lower surface of the light emitting device package; and a clamp disposed on a lead frame of the light emitting device package and fixing the lead frame and the light emitting device package to the heating block.

### CROSS-REFERENCE TO RELATED APPLICATIONS

This application claims the priority of Korean Patent Application No. 10-2011-0022761 filed on Mar. 15, 2011, in the Korean Intellectual Property Office, the disclosure of which is incorporated herein by reference.

### BACKGROUND OF THE INVENTION

1. Field of the Invention

The present invention relates to an apparatus for manufacturing a light emitting device package and a method of manufacturing a light emitting device package using the same.

2. Description of the Related Art

In general, a light emitting device uses the characteristics of a compound semiconductor to convert electrical energy into infrared or visible light rays. A light emitting diode is a kind of electroluminescence (EL) device, and a light emitting diode based on a group III-V compound semiconductor is in practical use. A group III nitride-based compound semiconductor is a direct-transition semiconductor. Because group III nitride-based compound semiconductors can operate in a stable manner at high temperatures, group III nitride-based compound semiconductors are widely used in light emitting devices such as light emitting diodes (LEDs) and laser diodes (LDs).

Since individual chips of these light emitting devices are operated by external electrical signals, electrodes for receiving the electrical signals are formed on surfaces of the light emitting devices and these electrodes are connected to lead frames formed of a conductive material. The electrodes of the light emitting device and the lead frames may be electrically connected in various manners. A wire-bonding method of making electrical connections through a bonding wire such as a high purity gold (Au) or aluminum (Al) wire using a capillary tube may be applied thereto. In the wire-bonding process, the lead frames having the light emitting device mounted thereon are fixed by a heating block and a clamp, and the lead frames and the light emitting device are preheated by the heating block. Here, in a case in which the wire-bonding process is performed in a state in which the light emitting device is not maintained at a constant temperature, the bonding wire may be broken, or the wire-bonding process may fail altogether.

### SUMMARY OF THE INVENTION

An aspect of the present invention provides an apparatus for manufacturing a light emitting device package allowing for improved manufacturing processes of a light emitting device package, particularly, being improved in terms of the reliability and efficiency of a wire-bonding process.

An aspect of the present invention also provides a method of manufacturing a light emitting device package improved in terms of the reliability and efficiency of a wire-bonding process.

According to an aspect of the present invention, there is provided as apparatus for manufacturing a light emitting device package, the apparatus including: a heating block including a recessed portion provided in an area in which a light emitting device package is disposed, and a protruding portion disposed within the recessed portion while corresponding to a recess formed in a lower surface of the light emitting device package; and a clamp disposed on a lead frame of the light emitting device package and fixing the lead frame and the light emitting device package to the heating block.

The heating block may have an upper surface disposed on the same plane as an upper surface of the protruding portion.

The recess formed in the lower surface of the light emitting device package may expose at least a portion of the lead frame disposed within the light emitting device package.

The lead frame exposed through the recess may have a light emitting device mounted thereon.

The clamp may include at least one window exposing the light emitting device package.

The recess formed in the lower surface of the light emitting device package may include a plurality of recesses.

According to another aspect of the present invention, there is provided a method of manufacturing a light emitting device package, the method including: preparing a heating block having at least one recessed portion and a protruding portion formed within the at least one recessed portion; disposing a light emitting device package in the at least one recessed portion such that a recess formed in the lower surface of the light emitting device package is disposed to correspond to the protruding portion; fixing the light emitting device package using a clamp disposed thereon; and wire-bonding a light emitting device disposed within the light emitting device package.

The disposing of the light emitting device package in the at least one recessed portion may include allowing the protruding portion and the lead frame exposed through the recess of the light emitting device package to contact one another.

The disposing of the light emitting device package in the at least one recessed portion may include allowing the lead frame disposed outwardly of the light emitting device package to contact an upper surface of the heating block.

The method may further include heating the heating block.

The clamp may include at least one window, and the clamp may allow the light emitting device package to be disposed within the window.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view of an apparatus for manufacturing a light emitting device package according to an embodiment of the present invention;

FIG. 2 is a schematic cross-sectional view of an apparatus for manufacturing a light emitting device package according to an embodiment of the present invention;

FIG. 3 is a schematic top view of an apparatus for manufacturing a light emitting device package according to an embodiment of the present invention;

FIG. 4 is a schematic perspective view of a light emitting device package applicable to an apparatus for manufacturing a light emitting device package according to an embodiment of the present invention; and

FIGS. 5 through 7 are schematic bottom views of light emitting device packages according to various embodiments of the present invention.

### DETAILED DESCRIPTION OF THE INVENTION

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of components maybe exaggerated for clarity, and the same reference numerals will be used throughout to designate the same or like components.

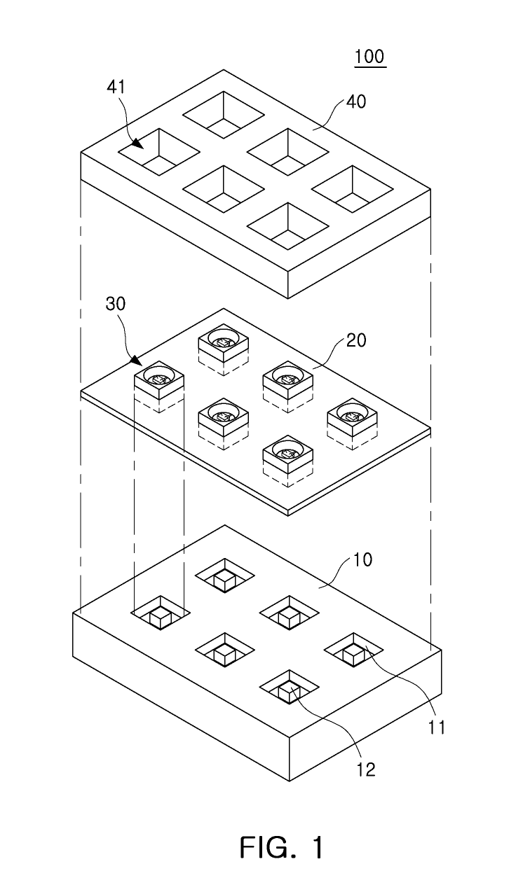

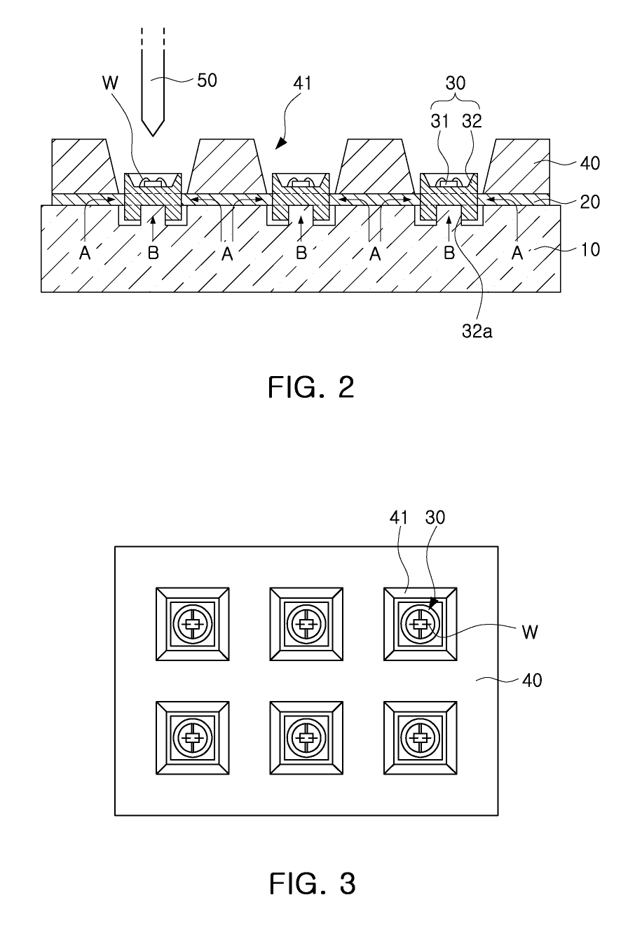

FIG. 1 is a schematic exploded perspective view of an apparatus for manufacturing a light emitting device package according to an embodiment of the present invention. FIG. 2 is a schematic cross-sectional view of an apparatus for manufacturing a light emitting device package according to an embodiment of the present invention. FIG. 3 is a schematic top view of an apparatus for manufacturing a light emitting device package according to an embodiment of the present invention. With reference to FIGS. 1 through 3, an apparatus 100 for manufacturing a light emitting device package may include a heating block 10 including a recessed portion 11 provided to house a light emitting device package 30 on an upper surface of the heating block 10 at the time of wire-bonding and a protruding portion 12 formed within the recessed portion 11, and a clamp 40 disposed on a lead frame 20 of the light emitting device package 30 and fixing the lead frame 20 to the heating block 10 to thereby bring them into contact with one another at the time of wire-bonding. Here, the light emitting device package 30 may have at least one recess 32a in a lower surface thereof, the recess 32a corresponding to the protruding portion 12.

The heating block 10 may be planar. The heating block 10 has a light emitting device 31 or the light emitting device package 30 disposed on the upper surface thereof at the time of wire-bonding and heats the lead frame 20, thereby providing heat required for wire-bonding to the light emitting device 31 by the lead frame 20. The heating block 10 may be formed of a metal having high thermal conductivity, and be heated by a heater (not shown). According to the present embodiment, the heating block 10 may have the recessed portion 11 provided to house the light emitting device package 30 therein. The recessed portion 11 may compensate for a step between the lower surface of the light emitting device package 30 and the lead frame 20 protruding from side surfaces of the light emitting device package 30. The lower surface of the light emitting device package 30 may be disposed within the recessed portion 11 of the heating block 10, and the lead frame 20 extending from the side surfaces of the light emitting device package 30 may be disposed on the upper surface of the heating block 10. The protruding portion 12 is formed within the recessed portion 11 of the heating block 10. The recess 32a corresponding to the protruding portion 12 is formed in the lower surface of the light emitting device package 30.

The light emitting device package 30 disposed on the heating block 10 may include the light emitting device 31, a package body 32 having an opening exposing the light emitting device 31, and the lead frame 20 having the light emitting device 31 disposed on an upper surface thereof and extending from the side surfaces of the package body 30. An electrode (not shown) formed on an upper surface of the light emitting device 31 may be wire-bonded to the lead frame 20 using a high purity gold (Au) or aluminum (Al) wire. In this case, two electrodes formed on the upper surface of the light emitting device 31 are wire-bonded to a pair of respective lead frames, or the light emitting device 31 is directly electrically connected to one lead frame provided as a mounting area for the light emitting device 31 without using a wire and is connected to the other lead frame using a conductive wire. A specific connection method may be variously modified according to necessity. In the present embodiment, a single light emitting device 31 is provided in a single light emitting device package 30. However, two or more light emitting devices may be provided therein. The light emitting device 31 may employ a photoelectric device emitting light when an electrical signal is applied thereto. A light emitting diode (LED) chip may be a representative light emitting device. For example, the light emitting device 31 may be a GaN-based LED chip emitting blue light.

The package body 32 of the light emitting device package 30 may be disposed to be opposed to a surface used for wire-bonding between the light emitting device 31 and the lead frame 20 and may serve to fix the lead frame 20. The package body 32 may be formed of a material having electrical insulation while being superior in thermal emission and light reflectivity properties; however, the material of the package body 32 is not particularly limited thereto. In light of this, the package body 32 may be formed of a transparent resin and have a structure in which light reflective particles, e.g., TiO₂, are dispersed in the transparent resin. The light emitting device package 30 may include the recess (not shown) in the lower surface thereof, the recess corresponding to the protruding portion 12 formed within the recessed portion 11 of the heating block 10. The recess formed in the lower surface of the light emitting device package 30 may expose the lead frame 20 disposed within the light emitting device package 30 such that the protruding portion 12 of the heating block 10 may directly contact the lead frame 20 exposed through the recess at the time of wire-bonding.

The lead frame 20 may be electrically connected to the light emitting device 31 using a conductive wire and serve as a terminal for applying external electrical signals to the light emitting device 31. To enable this, the lead frame 20 may be formed of a metal having superior electrical conductivity. With reference to FIG. 1, the lead frame 20 may be integrally formed as a single piece having a planar form with respect to the plurality of light emitting devices 30. After the wire-bonding process, a cutting process may be performed on the lead frame 20 to divide it into individual light emitting device packages 30 and a bending process may be further performed such that a portion of the lead frame 20, exposed outwardly through the side surface of the package body 32 so as to receive the electrical signals, is bent.

The clamp 40 may be disposed on the lead frame 20 and fix the lead frame 20 to the heating block 10 to thereby bring them into contact with one another at the time of wire-bonding. The clamp 40 is provided for the fixing of a wire-bonding apparatus, e.g., the heating block 10 and the light emitting device package 30 including the lead frame 20 during the wire-bonding process. The clamp 40 may have a plurality of windows 41 exposing the light emitting device packages 30. The clamp 40 presses the lead frame 20 placed on the upper portion of the heating block 10 while allowing the light emitting device package 30 to be disposed within the window 41 and fixes the lead frame 20 in place.

With reference to FIGS. 2 and 3, the heating block 10 may include the plurality of recessed portions 11 formed in areas in which the light emitting device packages 30 are disposed, and the protruding portions 12 formed within the individual recessed portions 11. The lower surface of each light emitting device package 30 disposed within the recessed portion 11 has the recess 32a in an area corresponding to the protruding portion 12. The lead frame 20 exposed through the recess 32a formed in the light emitting device package 30 directly contacts the protruding portion 12 of the heating block 10, such that heat from the heating block 10 may be easily transferred to the light emitting device 31. Specifically, when the light emitting device package 30 including the lead frame 20 is disposed within the recessed portion 11 of the heating block 10 and fixed by the clamp 40 disposed on the upper surface of the lead frame 20, heat generated from the heating block 10 preheated by a heater (not shown) is transferred to the light emitting device 31 through the lead frame 20. In a state in which the light emitting device 31 is preheated, the wire-bonding process is performed by a capillary tube 50 or the like.

As described in this embodiment, in the case that the light emitting device package 30 has the package body 32 and the lead frame 20 protruding from the side of the package body 32 and a step exists due to a difference between the lower surface of the package body 32 and the lower surface of the lead frame 20, the recessed portion 11 may be formed in the heating block 10 having the light emitting device package 30 disposed therein. Here, the lead frame and the heating block are disposed to directly contact one other.

In general, since the package body of the light emitting device package is formed of an insulating material, heat provided from the heating block for wire-bonding is transferred to the light emitting device through the lead frame exposed outwardly of the package body as indicated by arrows A in FIG. 2, and thus heat transfer efficiency from the heating block to the light emitting device is reduced. In a case in which a depth of the recessed portion formed in the heating block is not exactly identical to a distance from the lead frame to the lower surface of the package body, for example, the depth of the recessed portion is smaller than the distance from the lead frame to the lower surface of the package body, a gap between the lead frame and the upper surface of the heating block may occur, and accordingly, the wire-bonding process may be unsatisfactorily completed or may fail altogether.

In the present embodiment, as shown in FIG. 2, since the protruding portion 12 formed in the recessed portion 11 of the heating block 10 and the lead frame 20 exposed through the recess 32a formed in the lower surface of the light emitting device package 30 directly contact one another, as indicated by arrows B in FIG. 2, heat may be directly transferred to the light emitting device 31 through the lead frame 20 directly contacting the protruding portion 12 of the heating block 10. Further, an upper surface of the protruding portion 12 is disposed on the same plane as the upper surface of the heating block 10, such that heat transfer from the heating block 10 may be facilitated through the lead frame 20 disposed in the outside and inside of the package body 32 (see arrows A and B of FIG. 2). In addition, when the depth of the recessed portion 11 formed in the heating block 10 is designed to be greater than or equal to the distance from the lead frame 20 to the lower surface of the package body 32, a gap may not occur between the lead frame 20 and the heating block 10, and thus, heat transfer efficiency may be improved.

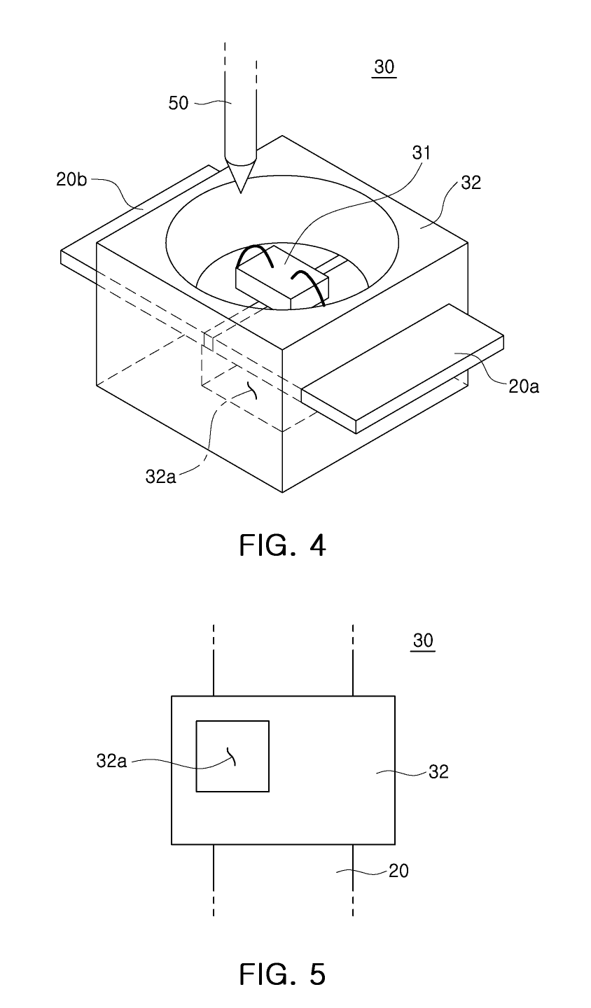

FIG. 4 is a schematic perspective view of a light emitting device package applicable to an apparatus for manufacturing a light emitting device package according to an embodiment of the present invention. With reference to FIG. 4, the light emitting device package 30 according to the present embodiment includes the recess 32a formed in the lower portion of the package body 32 as described above. The recess 32a may be engaged with the protruding portion 12 formed within the recessed portion 11 of the heating block 10. At the time of the wire-bonding process, the lead frame 20a and 20b exposed through the recess 32a and the protruding portion 12 directly contact one another such that heat provided by the heating block 10 may be effectively transferred to the light emitting device 31.

Meanwhile, since the recess 32a formed in the package body 32 exposes at least a portion of the lead frame 20, when the light emitting device package 30 according to the present embodiment is mounted on a circuit board (not shown), an improved heat release effect is achieved by the lead frame 20 exposed through the recess 32a. In order to improve heat release efficiency, the recess 32a may be filled with a material having high thermal conductivity such as copper, silver, aluminum or an alloy thereof. Meanwhile, as shown in FIG. 4, the lead frame 20 is cut into the individual light emitting device packages 30, each having the pair of electrically insulated lead frames 20a and 20b dividedly connected to the two electrodes of the light emitting device 31.

FIGS. 5 through 7 are schematic bottom views of light emitting device packages according to various embodiments of the present invention. As shown in FIGS. 5 through 7, the recess 32a, 32a′ or 32a″ exposing at least a portion of the lead frame in the lower surface of the package body 32, 32′ or 32″ may be modified in terms of the size, shape, and number thereof in various embodiments. In FIGS. 5 through 7, the recess has a rectangular shape; however, it will be obvious to those skilled in the art that the recess could have various shapes such as a triangular shape, a rectangular shape, a circular shape or the like.

With reference to FIG. 5, the recess 32a having a rectangular shape may be provided in the lower surface of the package body 32 of the light emitting device package 30 and the lead frame 20 exposed through the recess 32a may be a mounting area on which the light emitting device 31 is directly mounted. Since the recess 32a is formed in the direct lower portion of the lead frame having the light emitting device 31 mounted thereon, the lead frame 20 exposed through the recess 32a directly contacts the protruding portion 12 of the heating block 10 such that heat from the heating block 10 may be directly transferred to the light emitting device 31.

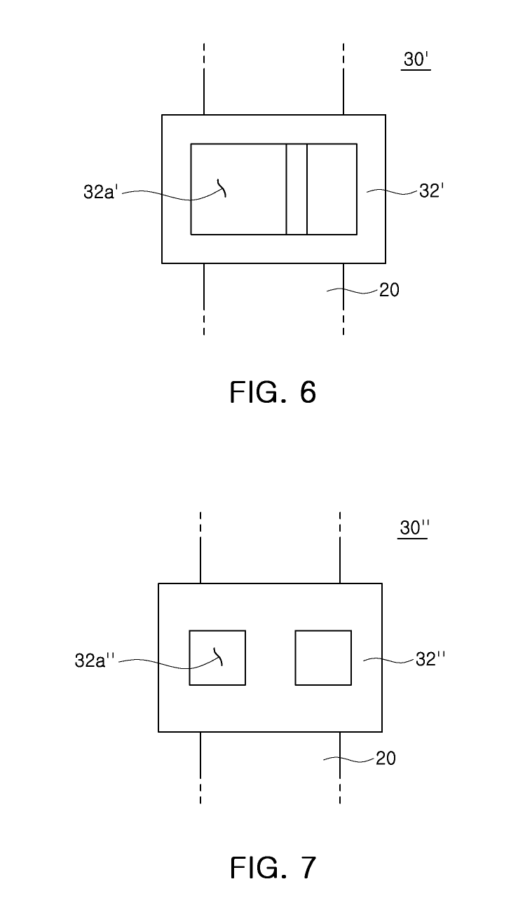

FIG. 6 shows a schematic bottom view of a lower surface of the package body 32′ of the light emitting device package 30′ according to another embodiment of the present invention. With reference to FIG. 6, the recess 32a′ may have a rectangular shape in a central portion of the lower surface of the package body 32′ such that a pair of lead frames 20 is exposed therethrough. As described in the present embodiment, in a case in which the size of the recess 32a′ formed in the lower surface of the package body 32′ is increased, heat transfer efficiency may be enhanced.

FIG. 7 shows a schematic bottom view of a lower surface of the package body 32″ of the light emitting device package 30″ according to another embodiment of the present invention. In this embodiment, a plurality of divided recesses 32a″ may be provided in the lower surface of the package body 32″ with respect to each of the pair of lead frames. In FIG. 7, two recesses 32a are shown; however, the number and shape thereof may be variously modified.

As set forth above, according to embodiments of the invention, an apparatus for manufacturing a light emitting device package allows for improved manufacturing processes of a light emitting device package, particularly, being improved in terms of the reliability and efficiency of a wire-bonding process.

According to embodiments of the invention, a method of manufacturing a light emitting device package has improved in terms of the reliability and efficiency of a wire-bonding efficiency.

While the present invention has been shown and described in connection with the embodiments, it will be apparent to those skilled in the art that modifications and variations can be made without departing from the spirit and scope of the invention as defined by the appended claims.

What is claimed is:

1. An apparatus for manufacturing a light emitting device package, the apparatus comprising:
a heating block including a recessed portion provided in an area in which a light emitting device package is disposed, and a protruding portion disposed within the recessed portion while corresponding to a recess formed in a lower surface of the light emitting device package; and
a clamp disposed on a lead frame of the light emitting device package and fixing the lead frame and the light emitting device package to the heating block.

2. The apparatus of claim 1, wherein the heating block has an upper surface disposed on the same plane as an upper surface of the protruding portion.

3. The apparatus of claim 1, wherein the recess formed in the lower surface of the light emitting device package exposes at least a portion of the lead frame disposed within the light emitting device package.

4. The apparatus of claim 3, wherein the lead frame exposed through the recess has a light emitting device mounted thereon.

5. The apparatus of claim 1, wherein the clamp includes at least one window exposing the light emitting device package.

6. The apparatus of claim 1, wherein the recess formed in the lower surface of the light emitting device package comprises a plurality of recesses.

7. A method of manufacturing a light emitting device package, the method comprising:
preparing a heating block having at least one recessed portion and a protruding portion formed within the at least one recessed portion;
disposing a light emitting device package in the at least one recessed portion such that a recess formed in the lower surface of the light emitting device package is disposed to correspond to the protruding portion;
fixing the light emitting device package using a clamp disposed thereon; and
wire-bonding a light emitting device disposed within the light emitting device package.

8. The method of claim 7, wherein the disposing of the light emitting device package in the at least one recessed portion comprises allowing the protruding portion and the lead frame exposed through the recess of the light emitting device package to contact one another.

9. The method of claim 7, wherein the disposing of the light emitting device package in the at least one recessed portion comprises allowing the lead frame disposed outwardly of the light emitting device package to contact an upper surface of the heating block.

10. The method of claim 7, further comprising heating the heating block.

11. The method of claim 7, wherein the clamp includes at least one window, and
the clamp allows the light emitting device package to be disposed within the window.
